(19) United States
(12) Patent Application Publication
(10) Pub. No.: US 2017/0179205 A1
(43) Pub. Date: Jun. 22, 2017

(54) ORGANIC LIGHT-EMITTING DISPLAY APPARATUS AND METHOD OF MANUFACTURING THE SAME

(71) Applicant: SAMSUNG DISPLAY CO., LTD., Yongin-Si (KR)

(72) Inventor: Youngil KIM, Yongin-Si (KR)

(21) Appl. No.: 15/244,279

(22) Filed: Aug. 23, 2016

(30) Foreign Application Priority Data
Dec. 18, 2015 (KR) 10-2015-0181850

(51) Int. Cl. H01L 27/32; H01L 51/00; H01L 51/50

(52) U.S. Cl. CPC H01L 27/3213; H01L 51/5088; H01L 51/5092; H01L 51/5056; H01L 51/5072; H01L 51/0001; H01L 27/3248

(57) ABSTRACT

An organic light-emitting display apparatus includes a thin film transistor on a substrate; a pixel electrode electrically connected to the thin film transistor; an insulating first lower intermediate layer that includes a first region that covers an edge part of the pixel electrode, and a second region that covers a central part of the pixel electrode: an adhesive layer disposed on at least a portion of the first lower intermediate layer and that is lyophilic with respect to the first lower intermediate layer; a second lower intermediate layer disposed on the adhesive layer; a light-emitting layer disposed on the second lower intermediate layer; and a counter electrode disposed on the light-emitting layer.

### CROSS-REFERENCE TO RELATED APPLICATION

This application claims priority under 35 U.S.C. §119 from, and the benefit of, Korean Patent Application No. 10-2015-0181850, filed on Dec. 18, 2015 in the Korean Intellectual Property Office, the contents of which are herein incorporated by reference in their entirety.

### BACKGROUND

1. Technical Field

One or more embodiments are directed to organic light-emitting display apparatuses and methods of manufacturing the same, and more particularly, to organic light-emitting display apparatuses having an organic light-emitting diode that has increased light-emitting quality and methods of manufacturing the same.

2. Discussion of the Related Art

A display apparatus, such as an organic light-emitting display apparatus or a liquid crystal display apparatus, includes a thin film transistor (TFT), a capacitor, and a plurality of wires. A substrate for manufacturing a display apparatus includes minute patterns of a TFT, a capacitor, and wires, and the display apparatus is operated by connections between the TFT, the capacitor, and the wires.

An organic light-emitting display apparatus includes an organic light-emitting diode that includes a hole injection electrode, an electrode injection electrode, and an organic light-emitting layer between the hole injection electrode and the electrode injection electrode. An organic light-emitting display apparatus is an emissive display in which excitons are generated by combining holes from the hole injection electrode and electrons from the electrode injection electrode in the organic light-emitting layer, and light is generated when an energy state of excitons decays from an excited state to a ground state.

An organic light-emitting display apparatus, being an emissive display, does not require an additional light source, and thus, can operate with a low voltage and is thin and light weight. Due to a wide viewing angle, high contrast, and a quick response time, applications of organic light-emitting display apparatuses has increased from personal mobile devices, such as MP3 players or mobile phones, to televisions.

### SUMMARY

One or more embodiments include organic light-emitting display apparatuses that include an organic light-emitting diode (OLED) and a circuit for driving the OLED.

In an OLED, pixels are defined by barrier ribs. The barrier ribs are formed of an organic material and cover an edge of a pixel electrode. A gas generated by the organic material that constitutes the barrier ribs may penetrate into an intermediate layer that includes a light-emitting layer included in the OLED. In this case, a lifetime of the OLED may be reduced by outgassing.

Also, at least some light emitted from the light-emitting layer may be externally emitted by being reflected or refracted by the barrier ribs, and thus, light-emitting quality may be reduced.

One or more embodiments include organic light-emitting display apparatuses having an OLED that has increased light-emitting quality and lifetime and reduced manufacturing costs, and methods of manufacturing an organic light-emitting display apparatus.

Additional aspects will be set forth in part in the description which follows and, in part, will be apparent from the description, or may be learned by practice of the presented embodiments.

According to one or more embodiments, an organic light-emitting display apparatus includes: a thin film transistor on a substrate; a pixel electrode electrically connected to the thin film transistor; a first lower intermediate layer that includes an insulating first region that covers an edge part of the pixel electrode and a second region that contacts a central part of the pixel electrode; an adhesive layer disposed on at least a portion of the first lower intermediate layer and that is a lyophilic with respect to the first lower intermediate layer; a second lower intermediate layer disposed on the adhesive layer; a light-emitting layer disposed on the second lower intermediate layer; and a counter electrode disposed on the light-emitting layer.

The adhesive layer, the second lower intermediate layer, and the light-emitting layer may correspond to the second region.

The first region and the second region may have a same material.

An area of the second region may be less than that of the pixel electrode.

A material of the first region may have an electrical conductivity of less than or equal to about 10⁻⁸ S/cm.

The adhesive layer may be more lyophilic with respect to the first lower intermediate layer than is the second lower intermediate layer with respect to the first lower intermediate layer.

The organic light-emitting display apparatus may further include an electron transport layer disposed between the light-emitting layer and the counter electrode and an electron injection layer disposed between the electron transport layer and the counter electrode.

The electron transport layer, the electron injection layer, and the counter electrode may correspond to the first region and the second region.

The adhesive layer may be thinner than the second lower intermediate layer.

A thickness of the adhesive layer may be less than or equal to about 10 nm.

According to one or more embodiments, a method of manufacturing an organic light-emitting display apparatus includes: forming a thin film transistor on a substrate; forming a pixel electrode electrically connected to the thin film transistor; forming a first lower intermediate layer that includes an insulating first region that covers an edge part of the pixel electrode and a second region that contacts a central part of the pixel electrode; forming an adhesive layer on at least a portion of the first lower intermediate layer, and the adhesive layer being lyophilic with respect to the first lower intermediate layer; forming a second lower intermediate layer on the adhesive layer; forming a light-emitting layer on the second lower intermediate layer; and forming a counter electrode on the light-emitting layer.

Forming the first lower intermediate layer may include forming a hole injection material that covers the pixel electrode and irradiating ultraviolet light onto a region of the hole injection material that corresponds to the first region using a first mask.

Irradiating ultraviolet light onto the hole injection material may include irradiating the ultraviolet light having an intensity of greater than or equal to about 6 J/cm² onto the hole injection material region corresponding to the first region.

Forming the adhesive layer may include forming an adhesive material that is lyophilic with respect to the first lower intermediate layer on the first lower intermediate layer and forming the adhesive layer by removing the adhesive material corresponding to the first region using a second mask.

Forming the second lower intermediate layer may include forming a hole transport material on the adhesive layer and drying the hole transport material.

Forming the light-emitting layer may include forming a light-emitting material on the second lower intermediate layer and drying the light-emitting material.

The method may further include forming an electron transport layer on the light-emitting layer, wherein the electron transport layer corresponds to the first region and the second region, and forming an electron injection layer on the electron transport layer, wherein the electron injection layer corresponds to the first region and the second region.

According to one or more embodiments, a method of manufacturing an organic light-emitting display apparatus includes forming a thin film transistor on a substrate; forming a pixel electrode electrically connected to the thin film transistor; forming a hole injection material that covers the pixel electrode; irradiating ultraviolet light onto of the hole injection material using a first mask wherein an insulating first region that covers an edge part of the pixel electrode and a second region that covers a central part of the pixel electrode are formed, wherein the first mask blocks the ultraviolet light from the second region; forming an adhesive material that is lyophilic with respect to the first lower intermediate layer on the first lower intermediate layer; and forming an adhesive layer on at least a portion of the first lower intermediate layer by removing the adhesive material corresponding to the first region of the first lower intermediate layer using a second mask, wherein the second mask is the same as the first mask.

The method may further include forming a second lower intermediate layer on the adhesive layer; forming a light-emitting layer on the second lower intermediate layer; and forming a counter electrode on the light-emitting layer.

The hole injection material may include poly(3,4-ethylenedioxythiophene (PEDOT), and the ultraviolet light irradiated onto of the hole injection material may have an intensity that is greater than or equal to about 6 J/cm² that can convert the PEDOT in the hole injection material corresponding to the first region into an insulator.

According to an embodiment, an organic light-emitting display apparatus having an OLED that has increased light-emitting quality and lifetime and reduced manufacturing costs, and a method of manufacturing the organic light-emitting display apparatus, may be provided.

The scope of the inventive concept is not limited to the effects described above.

### BRIEF DESCRIPTION OF THE DRAWINGS

FIG. 1 is a schematic plane view of an organic light-emitting display apparatus according to an embodiment.

FIG. 2 is a cross-sectional view of an organic light-emitting display apparatus according to an embodiment.

FIGS. 3A through 3F are cross-sectional views that sequentially illustrate a method of manufacturing an organic light-emitting display apparatus of FIG. 2, according to an embodiment.

FIG. 4 is a schematic cross-sectional view of an organic light-emitting display apparatus according to another embodiment.

FIG. 5 is a graph of the conductivity variation in a first intermediate layer as a function of light intensity irradiated onto the first intermediate layer of FIG. 2.

### DETAILED DESCRIPTION

Embodiments of the inventive concept may be modified into various forms and may have various embodiments. In this regard, a description of exemplary embodiments of the present disclosure will now be made in detail, examples of which are illustrated in the accompanying drawings. However, embodiments of the inventive concept may have different forms and should not be construed as being limited to the descriptions set forth herein.

Hereafter, embodiments of the inventive concept will be described more fully with reference to the accompanying drawings, in which exemplary embodiments of the inventive concept are shown. In describing the inventive concept with reference to drawings, like reference numerals may be used for elements that are substantially identical or correspond to each other, and the descriptions thereof will not be repeated.

Also, in the specification, when a layer, a film, a region, or a constituent element is referred to as being electrically connected, it can be directly electrically connected to other film, region, and constituent element, or can be indirectly electrically connected by intervening other film, region, and constituent element.

In the drawings, each of the elements is exaggerated for clarity and explanation convenience, and thus, the ratios of elements may be exaggerated or reduced.

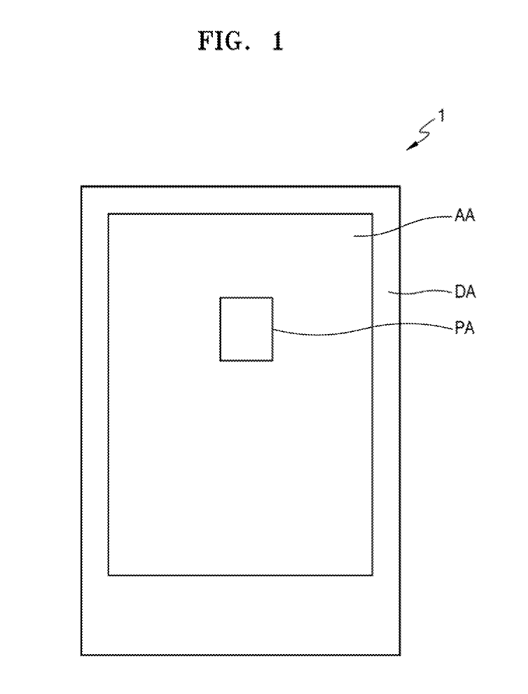

FIG. 1 is a schematic plane view of an organic light-emitting display apparatus 1 according to an embodiment.

Referring to FIG. 1, the organic light-emitting display apparatus 1 includes an active area AA and a dead area DA surrounding the active area AA. The active area AA includes pixel areas PA, and a pixel is included in each of the pixel areas PA. Each of the pixel areas PA includes a pixel circuit and an organic light-emitting diode (OLED) connected to the pixel circuit.

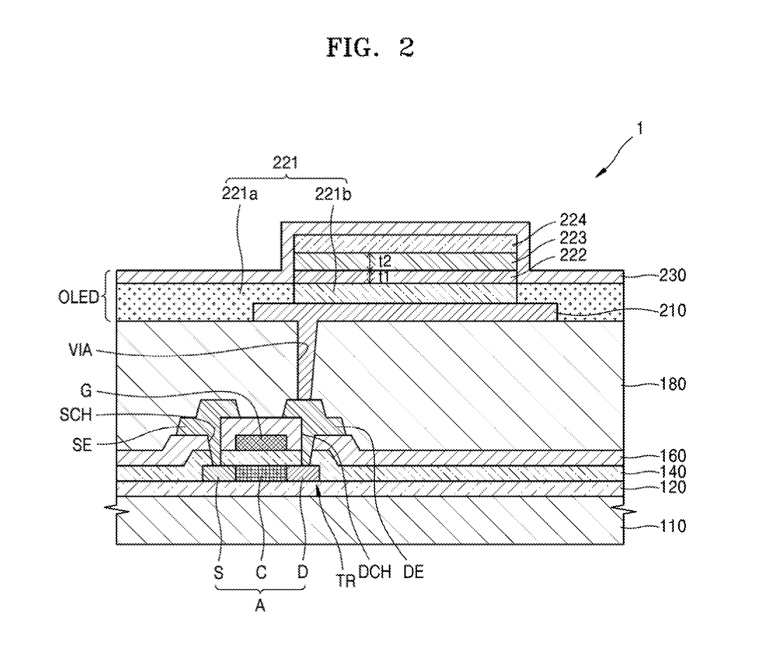

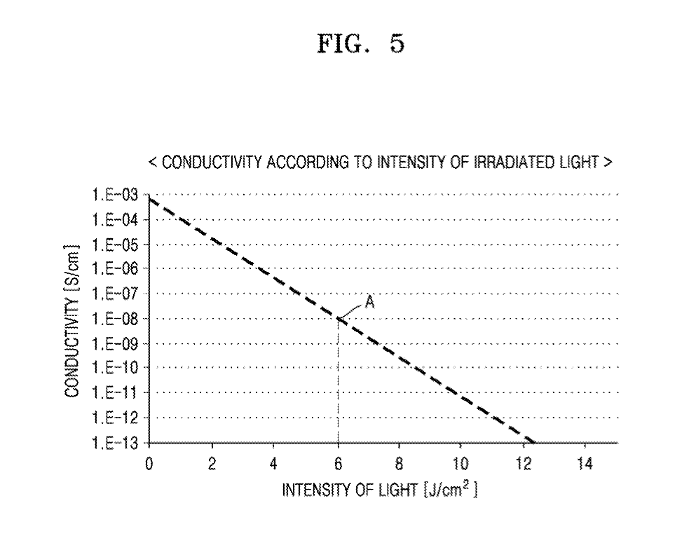

FIG. 2 is a cross-sectional view of an organic light-emitting display apparatus according to an embodiment, and FIG. 5 is a graph of the conductivity variation in a first intermediate layer as a function of light intensity irradiated onto the first intermediate layer of FIG. 2.

Referring to FIG. 2, the organic light-emitting display apparatus 1 according to a current embodiment includes a substrate 110, a transistor TR disposed on the substrate 110, a pixel electrode 210 electrically connected to the transistor TR, a first lower intermediate layer 221 that has an insulating first region 221a that covers an edge part of the pixel electrode 210 and a second region 221b that covers a central part of the pixel electrode 210, an adhesive layer 222 disposed on at least a portion of the first lower intermediate layer 221 and that is lyophilic with respect to the first lower intermediate layer 221, a second lower intermediate layer 223 disposed on the adhesive layer 222, a light-emitting layer 224 disposed on the second lower intermediate layer 223, and a counter electrode 230 disposed on the light-emitting layer 224.

The substrate 110 may be formed of various materials, such as glass, metal, or a plastic such as polyethylene terephthalate (PET), polyethylene naphthalate (PEN), polyimide, etc.

According to an embodiment, a buffer layer 120 is disposed on the substrate 110. The buffer layer 120 can prevent impurity elements from penetrating into the transistor TR from the substrate 110 and can planarize a surface of the substrate 110. The buffer layer 120 may include, for example, at least one of silicon oxide SiO₂ and silicon nitride SiNx. According to a current embodiment, the buffer layer 120 may include a single film of silicon oxide SiO₂, a single film of silicon nitride SiNx, or a double film structure in which silicon oxide SiO₂ and silicon nitride SiNx are stacked.

The transistor TR is disposed on the buffer layer 120. According to an embodiment, the transistor TR includes an active layer A, a gate electrode G, a source electrode SE, and a drain electrode DE.

The active layer A is made conductive by being doped with a dopant, and includes a source region S and a drain region D that are apart from each other by a channel region C therebetween that is formed of a semiconductor.

A gate insulating film 140 is disposed on the buffer layer 120 and covers the active layer A, and the gate electrode G is disposed on the gate insulating film 140 to correspond to at least a part of the active layer A.

The gate insulating film 140 may be a monolayer thin film or a multilayer thin film by including an inorganic material or an organic material. According to an embodiment, if the gate insulating film 140 is a monolayer thin film, the gate insulating film 140 is disposed between the active layer A and the gate electrode G, and includes silicon oxide SiO₂ or silicon nitride SiNx.

In addition, according to other embodiments, the gate insulating film 140 is a multilayer thin film. According to a current embodiment, the gate insulating film 140 includes a lower thin film formed of silicon oxide SiO₂ and an upper thin film formed of silicon nitride SiNx. When an etch-resistant silicon nitride SiNx layer is disposed on the silicon oxide SiO₂ layer, damage to the gate insulating film 140 can be reduced in a patterning process for forming the gate electrode G.

The gate electrode G may be formed of various conductive materials, such as magnesium Mg, aluminum Al, nickel Ni, chrome Cr, molybdenum Mo, tungsten W, molybdenum tungsten MoW, and gold Au.

According to an embodiment, an interlayer insulating layer 160 is disposed on the gate insulating film 140 and covers the gate electrode G. The interlayer insulating layer 160 may include silicon oxide SiO₂ or silicon nitride SiNx.

According to an embodiment, the gate insulating film 140 and the interlayer insulating layer 160 each include a source contact hole SCH and a drain contact hole DCH that respectively expose the source region S and the drain region D.

According to an embodiment, the source electrode SE and the drain electrode DE of the transistor TR are disposed on the interlayer insulating layer 160. The source electrode SE and the drain electrode DE are respectively connected to the source region S and the drain region D through the source contact hole SCH and the drain contact hole DCH.

According to an embodiment, a via insulating film 180 is disposed on the interlayer insulating layer 160 and covers the source electrode SE and the drain electrode DE. According to a current embodiment, the via insulating film 180 can be formed of an organic material, such as an acryl group organic material, polyimide, benzocyclobutene (BCB), etc., or an inorganic material, such as silicon nitride SiNx. The via insulating film 180 can protect elements, such as the transistor TR disposed below the via insulating film 180 and can planarize an upper surface thereof by removing step differences caused by the pixel circuit.

According to an embodiment, the via insulating film 180 includes a via hole VIA that exposes the drain electrode DE of the transistor TR. The drain electrode DE of the transistor TR is filled in the drain contact hole DCH in the interlayer insulating layer 160. The drain electrode DE and the pixel electrode 210 of the OLED can be electrically connected to each other through the via hole VIA. That is, the pixel electrode 210 can be electrically connected to the transistor TR through the drain contact hole DCH and the via hole VIA.

According to an embodiment, the pixel electrode 210 of the OLED is disposed on the via insulating film 180. The pixel electrode 210 is formed of a material having a high work function. According to a current embodiment, the organic light-emitting display apparatus 1 is a top emission type in which an image is displayed away from the substrate 110. In this case, the pixel electrode 210 includes a metal reflection film formed of Ag, Mg, Al, Pt, Pd, Au, Ni, Nd, Ir, Cr, etc., and a transparent conductive film formed of indium tin oxide (ITO), indium zinc oxide (IZO), zinc oxide (ZnO), indium tin zinc oxide (ITZO), etc. According to another embodiment, the organic light-emitting display apparatus 1 is a bottom emission type in which an image is displayed toward the substrate 110. In this case, the pixel electrode 210 includes a transparent conductive film formed of ITO, IZO, ZnO, or ITZO, and the organic light-emitting display apparatus 1 further includes a semi-transparent metal film.

According to an embodiment, the first lower intermediate layer 221 is disposed on the via insulating film 180. The first lower intermediate layer 221 includes the first region 221a that covers an edge part of the pixel electrode 210 and the second region 221b that covers a central part of the pixel electrode 210. The first region 221a of the first lower intermediate layer 221 covers the edge part of the pixel electrode 210 at least 3 μm.

According to an embodiment, the first and second regions 221a and 221b include the same material. According to a current embodiment, the first and second regions 221a and 221b include poly(3,4-ethylenedioxythiophene) (PEDOT). When ultraviolet light is irradiated onto PEDOT, the conductivity of PEDOT is reduced, and when the ultraviolet light intensity irradiated onto PEDOT exceeds a certain value, the PEDOT becomes an insulator.

Referring to FIG. 5, the conductivity of PEDOT is inversely proportional to the intensity of the irradiated ultraviolet light. According to a current embodiment, when the intensity of ultraviolet light being irradiated onto PEDOT exceeds approximately 6 J/cm² (point A), the conductivity of the first region 221a of the first lower intermediate layer 221 is reduced to approximately 10⁻⁸ S/cm or less, and the PEDOT in the first region 221a becomes an insulator.

Referring to FIG. 2, compounds included in the first and second regions 221a and 221b are not limited to PEDOT. That is, the first and second regions 221a and 221b may include phthalocyanine compounds, such as copper phthalocyanine, a di-amine or triple-amine, such as (N,N′-diphenyl-N,N′-bis-[4-(phenyl-m-tolyl-amino)-phenyl]-biphenyl-4,4′-diamine (DNTPD), (4,4′,4″-tris(3-methylphenylphenylamino) triphenylamine (m-MTDATA), 4,4′4″-Tris(N,N-diphenylamino)triphenylamine (TDATA), or 4,4′,4″-tris{N,-(2-naphthyl)-N-phenylamino}-tr phenylamine (2TNATA), or a polymer compound, such as poly(3,4-ethylenedioxythiophene)/poly(4-styrenesulfonate) (PEDOT/PSS), polyaniline/dodecylbenzenesulfonic acid (PANI/DBSA), polyaniline/camphor sulfonicacid (PANI/CSA), or (polyaniline)/poly(4-styrenesulfonate (PANI/PSS).

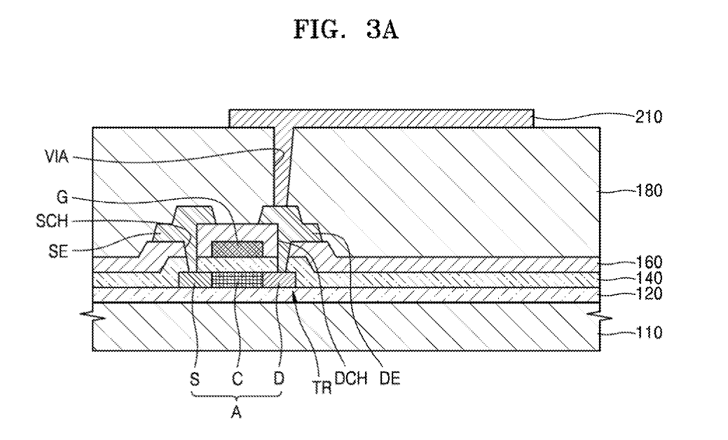

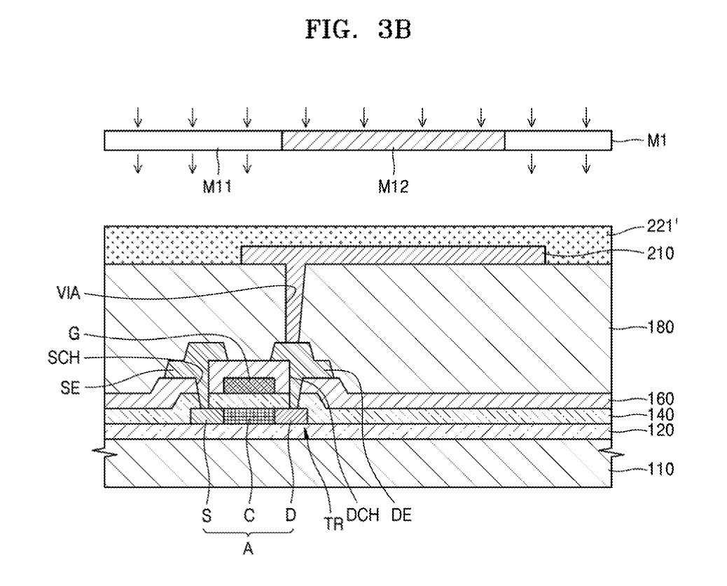

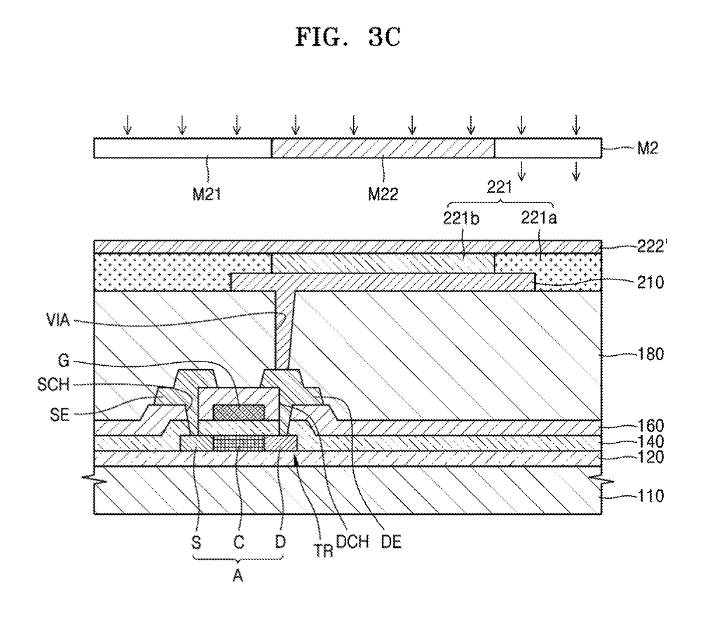

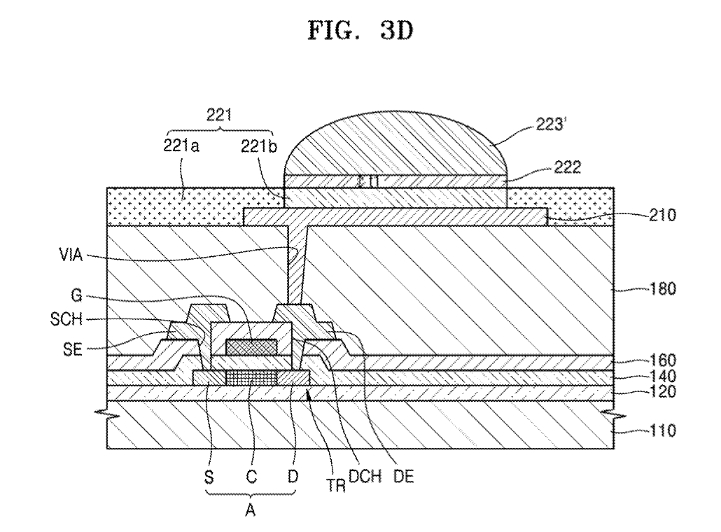

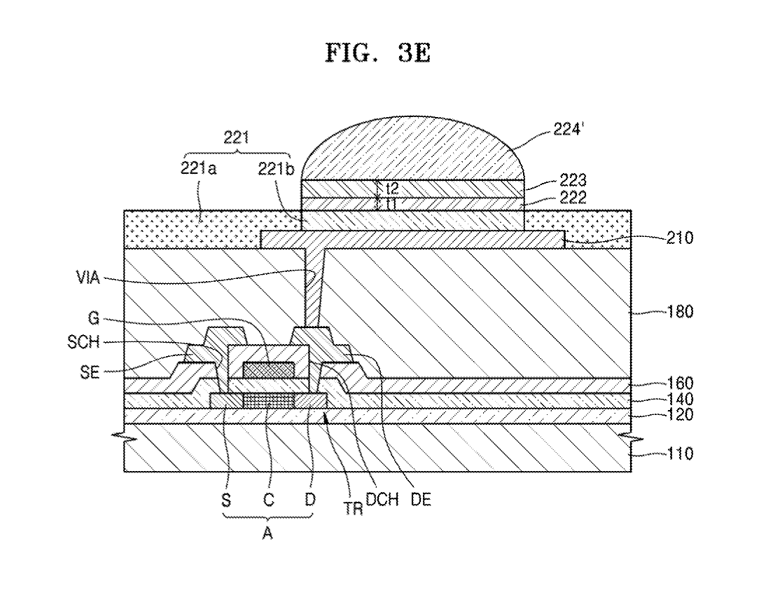

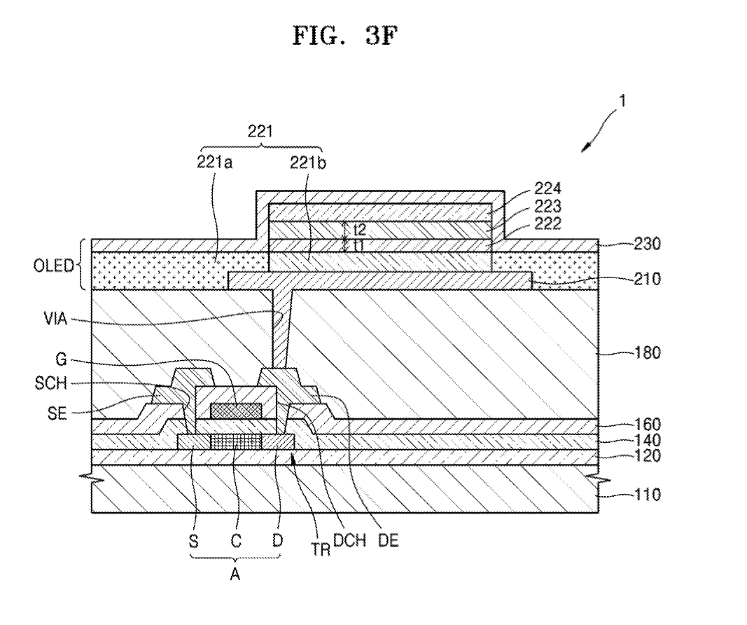

According to an embodiment, the first region 221a includes an insulating material. For example, the conductivity of the first region 221a of the first lower intermediate layer 221 is approximately 10⁻⁸ S/cm or less. According to a current embodiment, after a hole injection material 221 (see FIG. 3B) is formed on the via insulating film 180 and covers the pixel electrode 210, an insulating material is included in the first region 221a by irradiating ultraviolet light to the first region 221a. Accordingly, the pixel areas PA can be defined by covering an edge part of the pixel electrode 210 with the first region 221a of the first lower intermediate layer 221, without disposing an additional organic insulating material on the via insulating film 180, which can prevent OLED characteristics from changing due to gases generated from an organic insulating material in a process of manufacturing the OLED.

According to an embodiment, the second region 221b of the first lower intermediate layer 221 covers a central part of the pixel electrode 210, and includes a conductive material. The second region 221b directly contacts the first region 221a of the first lower intermediate layer 221. That is, the second region 221b has an area smaller than that of the pixel electrode 210.

According to an embodiment, the second region 221b of the first lower intermediate layer 221 can inject holes from the pixel electrode 210 into the light-emitting layer 224.

According to an embodiment, the adhesive layer 222 is disposed on at least a portion of the first lower intermediate layer 221, and the second lower intermediate layer 223 is disposed on the adhesive layer 222. According to a current embodiment, the adhesive layer 222 and the second lower intermediate layer 223 are disposed to correspond to the second region 221b. That is, the adhesive layer 222 and the second lower intermediate layer 223 are disposed on the second region 221b but not on the first region 221a. A thickness of the adhesive layer 222 is less than that of the second lower intermediate layer 223, and may be, for example, approximately 10 nm or less.

According to an embodiment, the adhesive layer 222 is formed of a material that is lyophilic with respect to the first lower intermediate layer 221. According to a current embodiment, the adhesive layer 222 is more lyophilic with respect to the first lower intermediate layer 221 than is the second lower intermediate layer 223 with respect to the first lower intermediate layer 221. Accordingly, although the second lower intermediate layer 223 is not directly disposed on the first lower intermediate layer 221, due to the lower lyophilic of the second lower intermediate layer 223 with respect to the first lower intermediate layer 221, the second lower intermediate layer 223 can be disposed on the first lower intermediate layer 221 because the more lyophilic adhesive layer 222 is disposed on the first lower intermediate layer 221. At this point, the second lower intermediate layer 223 is formed of a material that is lyophilic with respect to the adhesive layer 222. That is, the adhesive layer 222 is formed to be very thin, and thus is lyophilic with respect to both the first lower intermediate layer 221 and the second lower intermediate layer 223. Accordingly, the adhesive layer 222 can facilitate forming of the first lower intermediate layer 221 on the second lower intermediate layer 223.

According to an embodiment, the second lower intermediate layer 223 can transport holes to the light-emitting layer 224.

The adhesive layer 222 and the second lower intermediate layer 223 may each include, for example, a carbazole derivative, such as N-phenyl carbazole, polyvinyl carbazole; a triphenyl amine group compound, such as N,N′-bis(3-methylphenyl)-N,N′-diphenyl-[1,1-biphenyl]-4,4′-diamine (TPD) or 4,4′,4″-tris(Ncarbazolyl)triphenylamine (TCTA); or N,N′-di(1-naphthyl)-N,N′-diphenylbenzidine (NPB), etc.

According to an embodiment, the light-emitting layer 224 is disposed on the second lower intermediate layer 223. The light-emitting layer 224 may emit red, green, blue, or white light.

According to an embodiment, the light-emitting layer 224 includes a host material and a dopant material.

The host may be, for example, tris-8-hydroxyquinoline aluminium (Alq3), CBP(4,4′-bis(N-carbazolyl)-1,1-biphenyl (CBP), poly(n-vinyl carbazole (PVK), poly(n-vinyl carbazole, 9,10-di(naphthalene-2-yl) anthracene (ADN), 4,4′,4″-Tris(carbazol-9-yl)-triphenylamine (TCTA), 1,3,5-tris(N-phenylbenzimidazole-2-yl)benzene (TPBI), 3-tert-butyl-9,10-di(naphth-2-yl)anthracene (TBADN), distyrylarylene (DSA), E3 or CDBP(4,4′-bis(9-carbazolyl)-2,2′-dimethyl-biphenyl (CDBP).

The dopant may be, for example, Pt(II) octaethylporphine (PtOEP), tris(2-phenylisoquinoline)iridium (Ir(piq)3), bis(2-(2′-benzothienyl)-pyridinato-N,C3′)iridium(acetylacetonate) (Btp2Ir(acac), tris(2-phenylpyridine) iridium (Ir(ppy)3), Bis(2-phenylpyridine)(Acetylacetonato)iridium(III) (Ir(ppy)2(acac), tris(2-(4-tolyl)phenylpiridine)iridium (Ir(mppy)3), 10-(2-benzothiazolyl)-1,1,7,7-tetramethyl-2,3,6,7-tetrahydro-1H,5H,11H-[1]benzopyrano [6,7,8-ij]-quinolizin-11-one (C545T), Bis[3,5-difluoro-2-(2-pyridyl)phenyl](picolinato)iridium(III) (F2Irpic), (F2ppy)2Ir(tmd), Ir(dfppz)3, 4,4′-bis(2,2′-diphenylethen-1-yl)biphenyl (DPVBi), 4,4′-Bis[4-(diphenylamino)styryl]biphenyl (DPAVBi), or TBPe (2,5,8,11-tetra-tert-butylperylene (TBPe).

According to an embodiment, the counter electrode 230 is disposed on the light-emitting layer 224. The counter electrode 230 extends from the second region 221b to the first region 221a to cover the first lower intermediate layer 221. That is, the counter electrode 230 is disposed to correspond to the first region 221a and the second region 221b. If the organic light-emitting display apparatus 1 is a top emission type, the counter electrode 230 is a transparent or semi-transparent electrode. If the organic light-emitting display apparatus 1 is a bottom emission type, the counter electrode 230 is a reflective electrode. The counter electrode 230 is formed of an alloy having a low work function.

In addition, an encapsulating substrate or an encapsulating layer may be disposed on the counter electrode 230.

According to the above descriptions, an organic light-emitting display apparatus 1 having a reduced number of manufacturing processes and high resolution may be realized by improving characteristics of an OLED. In addition, the lifetime of the OLED may be increased.

Hereinafter, some repeated descriptions may be omitted or simplified.

FIGS. 3A through 3F are cross-sectional views that sequentially illustrate a method of manufacturing the organic light-emitting display apparatus 1 of FIG. 2, according to an embodiment.

Referring to FIG. 3A, the buffer layer 120 is formed on the substrate 110, and the transistor TR is formed on the buffer layer 120. The transistor TR includes the active layer A, the gate electrode G, the source electrode SE, and the drain electrode DE.

Next, the via insulating film 180 that covers the transistor TR is formed, and the pixel electrode 210 is formed on the via insulating film 180. The pixel electrode 210 is electrically connected to the transistor TR through the via hole VIA.

Referring to FIG. 3B, the hole injection material 221′ is formed on the via insulating film 180 to cover the pixel electrode 210, The hole injection material 221′ can be formed via an inkjet printing method, a screen printing method, a spray printing method, a spin coating method, a slit coating method, etc. At this point, the hole injection material 221′ is formed of PEDOT.

Next, ultraviolet light is irradiated onto the hole injection material 221′ using a first mask M1 that includes a first transmission unit M11 that transmits light and a first blocking unit M12 that blocks light. The first transmission unit M11 masks a region of the hole injection material 221′ that corresponds to the edge part of the pixel electrode 210 except for the central part of the pixel electrode 210 and the first blocking unit M12 masks the remaining region of the hole injection material 221′. Accordingly, ultraviolet light propagates through the first transmission unit M11 to be irradiated onto a region of the hole injection material 221′ that includes the edge part of the pixel electrode 210. However, ultraviolet light is blocked from irradiating the central part of the hole injection material 221′ by the first blocking unit M12.

According to a current embodiment, ultraviolet light intensity of approximately 6 J/cm² or above is irradiated onto the hole injection material 221′. As a result of being irradiated by ultraviolet light, the first lower intermediate layer 221 is formed, including the insulating first region 221a (see FIG. 3C) that covers the edge part of the pixel electrode 210 and the second region 221b (see FIG. 3C) that covers the central part of the pixel electrode 210. At this point, a conductivity of a material of the first region 221a (see FIG. 3C) has been reduced to less than or equal to about 10⁻⁸ S/cm due to being irradiated by ultraviolet light of intensity of greater than or equal to about 6 J/cm², and thus, the material has become an insulator.

Referring to FIG. 3C, an adhesive material 222′ is formed on the first lower intermediate layer 221. The adhesive material 222′ may be formed via an inkjet printing method, a screen printing method, a spray printing method, a spin coating method, a slit coating method, etc. According to a current embodiment, the adhesive material 222′ has a thickness of approximately 10 nm or less, and thus, is lyophilic with respect to the first lower intermediate layer 221 and the second lower intermediate layer 223.

Next, light is irradiated onto the adhesive material 222′ using a second mask M2 that includes a second light transmission unit M21 that transmits light and a second light blocking unit M22 that blocks light. Accordingly, light is blocked from the adhesive material 222′ region corresponding to the second region 221b of the first lower intermediate layer 221, and light is irradiated onto the adhesive material 222′ region corresponding to the first region 221a of the first lower intermediate layer 221.

The second mask M2 is the same as the first mask M1. A single mask can be used for a plurality of processes, which can reduce manufacturing costs.

After irradiating light onto the adhesive material 222′, the adhesive layer 222 (see FIG. 3D) is formed by removing the portion of the adhesive material 222′ on which the light was irradiated, that is, the portion corresponding to the first region 221a of the first lower intermediate layer 221.

Referring to FIG. 3D, a hole transport material 223′ is formed on the adhesive layer 222. The hole transport material 223′ is formed to correspond to the second region 221b of the first lower intermediate layer 221 on which the adhesive layer 222 is formed via an inkjet printing method, a screen printing method, a spray printing method, a spin coating method, a slit coating method, etc. That is, the hole transport material 223′ is not formed on the first region 221a of the first lower intermediate layer 221.

Next, the second lower intermediate layer 223 (see FIG. 3E) is formed on the adhesive layer 222 by drying the hole transport material 223′. A second thickness t2 of the second lower intermediate layer 223 is greater than a first thickness t1 of the adhesive layer 222.

Referring to FIG. 3E, a light-emitting material 224′ is formed on the second lower intermediate layer 223. The light-emitting material 224′ is formed to correspond to the second region 221b of the first lower intermediate layer 221 on which the second lower intermediate layer 223 is formed via an inkjet printing method, a screen printing method, a spray printing method, a spin coating method, a slit coating method, etc. That is, the light-emitting material 224′ is not formed on the first region 221a of the first lower intermediate layer 221.

Next, the light-emitting layer 224 (see FIG. 3F) is formed on the second lower intermediate layer 223 by drying the light-emitting material 224′.

Referring to FIG. 3F, the counter electrode 230 that covers the first lower intermediate layer 221, the adhesive layer 222, the second lower intermediate layer 223, and the light-emitting layer 224 is formed. The counter electrode 230 is formed on the first region 221a and the second region 221b of the first lower intermediate layer 221.

According to a current embodiment, the hole injecting second region 221b of the first lower intermediate layer 221, the hole transporting second lower intermediate layer 223, and the light-emitting layer 224 are formed on a central region of the pixel electrode 210, not the edge region thereof, and thus pixels can be defined without disposing additional organic barrier ribs. Accordingly, since a process for manufacturing barrier ribs has been eliminated, manufacturing costs can be reduced, an effect of reduced light-emission from an OLED due to the barrier ribs can be addressed, and a effect of reduced OLED lifetime due to gases generated by an organic barrier rib material can be addressed. In addition, a single mask is used in a process of manufacturing the first lower intermediate layer 221 and the adhesive layer 222, and thus, manufacturing costs can be reduced.

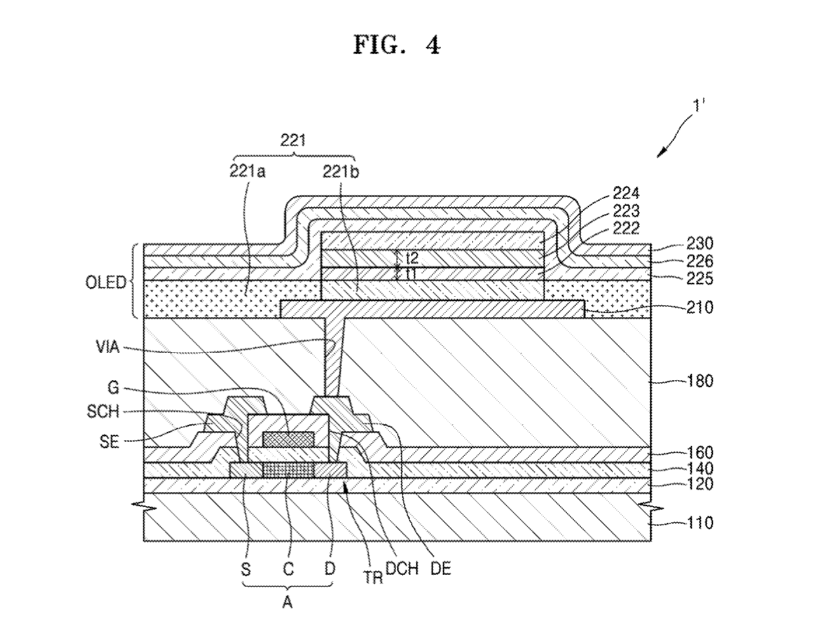

FIG. 4 is a schematic cross-sectional view of an organic light-emitting display apparatus 1′ according to another embodiment.

Referring to FIG. 4, the organic light-emitting display apparatus 1′ according to a current embodiment includes a substrate 110, a transistor TR on the substrate 110, a pixel electrode 210 electrically connected to the transistor TR, a first lower intermediate layer 221 that includes an insulating first region 221a that covers an edge of the pixel electrode 210, and a second region 221b that covers a central part of the pixel electrode 210, an adhesive layer 222 that is on at least a portion of the first lower intermediate layer 221 and that is lyophilic with respect to the first lower intermediate layer 221, a second lower intermediate layer 223 on the adhesive layer 222, a light-emitting layer 224 on the second lower intermediate layer 223, an electron transport layer 225 on the light-emitting layer 224, an electron injection layer 226 on the electron transport layer 225, and a counter electrode 230 on the electron injection layer 226.

According to an embodiment, the electron transport layer 225 and the electron injection layer 226 on the light-emitting layer 224 may be respectively referred to as a first upper intermediate layer and a second upper intermediate layer with respect to the first lower intermediate layer 221 and the second lower intermediate layer 223.

According to an embodiment, the electron transport layer 225 is disposed on the second region 221b on which the adhesive layer 222, the second lower intermediate layer 223, and the light-emitting layer 224 are disposed, and extends from the second region 221b to the first region 221a and covers the first lower intermediate layer 221. That is, the electron transport layer 225 corresponds to the first region 221a and the second region 221b.

The electron transport layer 225 may include, for example, 2,9-Dimethyl-4,7-diphenyl-1,10-phenanthroline (Alq3, BCP), 4,7-Diphenyl-1,10-phenanthroline (Bphen), 3-(4-Biphenylyl)-4-phenyl-5-tert-butylphenyl-1,2,4-triazole (TAZ), 4-(Naphthalen-1-yl)-3,5-diphenyl-4H-1,2,4-triazole (NTAZ), 2-(4-Biphenylyl)-5-(4-tert-butylphenyl)-1,3,4-oxadiazole (tBu-PBD), Bis(2-methyl-8-quinolinolato-N1,O8)-(1,1′-Biphenyl-4-olato)aluminum (BAlq), beryllium bis(benzoquinolin-10-olate (Bebq2), 9,10-di(naphthalene-2-yl)anthrascene (ADN), etc.

According to an embodiment, the electron injection layer 226 is disposed on the second region 221b on which the adhesive layer 222, the second lower intermediate layer 223, the light-emitting layer 224, and the electron transport layer 225 are disposed, and extends from the second region 221b to the first region 221a and covers the first lower intermediate layer 221. That the electron injection layer 226 corresponds to the first region 221a and the second region 221b.

The electron injection layer 226 may include at least one of, for example, LiCl, NaCl, KCl, RbCl, CsCl, Yb, Sc, V, Y, In, Ce, Sm, Eu, and Tb.

According to an embodiment, the counter electrode 230 is disposed on the second region 221b on which the adhesive layer 222, the second lower intermediate layer 223, the light-emitting layer 224, the electron transport layer 225, and the electron injection layer 226 are disposed, and extends from the second region 221b to the first region 221a. That is, the counter electrode 230 corresponds to the first region 221a and the second region 221b.

In addition, an encapsulating substrate or an encapsulating layer may be disposed on the counter electrode 230.

While one or more exemplary embodiments have been described with reference to the figures, it will be understood by those of ordinary skill in the art that various changes in form and details may be made therein without departing from the spirit and scope as defined by the following claims.

What is claimed is:

1. An organic light-emitting display apparatus comprising:
a thin film transistor on a substrate;
a pixel electrode electrically connected to the thin film transistor;
a first lower intermediate layer that includes an insulating first region that covers an edge part of the pixel electrode and a second region that contacts a central part of the pixel electrode;
an adhesive layer disposed on at least a portion of the first lower intermediate layer and that is lyophilic with respect to the first lower intermediate layer;
a second lower intermediate layer disposed on the adhesive layer;
a light-emitting layer disposed on the second lower intermediate layer; and
a counter electrode disposed on the light-emitting layer.

2. The organic light-emitting display apparatus of claim 1, wherein the adhesive layer, the second lower intermediate layer, and the light-emitting layer correspond to the second region of the first lower intermediate layer.

3. The organic light-emitting display apparatus of claim 1, wherein the first region and the second region of the first lower intermediate layer include a same material.

4. The organic light-emitting display apparatus of claim 1, wherein an area of the second region of the first lower intermediate layer is less than that of the pixel electrode.

5. The organic light-emitting display apparatus of claim 1, wherein a material of the first region of the first lower intermediate layer has an electrical conductivity of less than or equal to about 10⁻⁸ S/cm.

6. The organic light-emitting display apparatus of claim 1, wherein the adhesive layer is more lyophilic with respect to the first lower intermediate layer than is the second lower intermediate layer with respect to the first lower intermediate layer.

7. The organic light-emitting display apparatus of claim 1, further comprising:
an electron transport layer disposed between the light-emitting layer and the counter electrode; and
an electron injection layer disposed between the electron transport layer and the counter electrode.

8. The organic light-emitting display apparatus of claim 7, wherein the electron transport layer, the electron injection layer, and the counter electrode correspond to the first region and the second region of the first lower intermediate layer.

9. The organic light-emitting display apparatus of claim 1, wherein the adhesive layer is thinner than the second lower intermediate layer.

10. The organic light-emitting display apparatus of claim 9, wherein a thickness of the adhesive layer is less than or equal to about 10 nm.

11. A method of manufacturing an organic light-emitting display apparatus, the method comprising:
forming a thin film transistor on a substrate;
forming a pixel electrode electrically connected to the thin film transistor;
forming a first lower intermediate layer that includes an insulating first region that covers an edge part of the pixel electrode and a second region that contacts a central part of the pixel electrode;
forming an adhesive layer on at least a portion of the first lower intermediate layer, the adhesive layer being lyophilic with respect to the first lower intermediate layer;
forming a second lower intermediate layer on the adhesive layer;
forming a light-emitting layer on the second lower intermediate layer; and
forming a counter electrode on the light-emitting layer.

12. The method of claim 11, wherein forming the first lower intermediate layer comprises:
forming a hole injection material that covers the pixel electrode; and
irradiating ultraviolet light onto a region of the hole injection material that corresponds to the first region of the first lower intermediate layer using a first mask.

13. The method of claim 12, wherein irradiating ultraviolet light onto the hole injection material comprises irradiating ultraviolet light having an intensity of greater than or equal to about 6 J/cm² onto the hole injection material region corresponding to the first region of the first lower intermediate layer.

14. The method of claim 11, wherein forming the adhesive layer comprises:
forming an adhesive material that is lyophilic with respect to the first lower intermediate layer on the first lower intermediate layer; and
forming the adhesive layer by removing the adhesive material corresponding to the first region of the first lower intermediate layer using a second mask.

15. The method of claim 11, wherein forming the second lower intermediate layer comprises:
forming a hole transport material on the adhesive layer; and
drying the hole transport material.

16. The method of claim 11, wherein forming of light-emitting layer comprises:
forming a light-emitting material on the second lower intermediate layer; and
drying the light-emitting material.

17. The method of claim 11, further comprising:
forming an electron transport layer on the light-emitting layer, wherein the electron transport layer corresponds to the first region and the second region of the first lower intermediate layer; and
forming an electron injection layer on the electron transport layer, wherein the electron injection layer corresponds to the first region and the second region of the first lower intermediate layer.

18. A method of manufacturing an organic light-emitting display apparatus, the method comprising:
forming a thin film transistor on a substrate;
forming a pixel electrode electrically connected to the thin film transistor;
forming a hole injection material that covers the pixel electrode;
irradiating ultraviolet light onto of the hole injection material using a first mask wherein an insulating first region that covers an edge part of the pixel electrode and a second region that contacts a central part of the pixel electrode are formed, wherein the first mask blocks the ultraviolet light from the second region;
forming an adhesive material that is lyophilic with respect to the first lower intermediate layer on the first lower intermediate layer; and
forming an adhesive layer on at least a portion of the first lower intermediate layer by removing the adhesive material corresponding to the first region of the first lower intermediate layer using a second mask,
wherein the second mask is the same as the first mask.

19. The method of claim 18, further comprising:
forming a second lower intermediate layer on the adhesive layer;
forming a light-emitting layer on the second lower intermediate layer; and
forming a counter electrode on the light-emitting layer.

20. The method of claim 18, wherein the hole injection material includes poly(3,4-ethylenedioxythiophene) (PEDOT),
wherein the ultraviolet light irradiated onto of the hole injection material has an intensity that is greater than or equal to about 6 J/cm² that converts the PEDOT in the hole injection material corresponding to the first region into an insulator.
